(19) United States
(12) Patent Application Publication
(10) Pub. No.: US 2008/0121983 A1
(43) Pub. Date: May 29, 2008

(54) Gate and method of forming the same, and memory device and method of manufacturing the same

(76) Inventors: Geum-Jung Seong, Yongin-si (KR); Gil-Heyun Choi, Seoul (KR); Byung-Hee Kim, Seoul (KR); Tae-Ho Cha, Seongnam-si (KR); Hee-Sook Park, Seoul (KR); Jang-Hee Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/606,899

(22) Filed: Dec. 1, 2006

(30) Foreign Application Priority Data
Sep. 22, 2006 (KR) 2006-92177

(51) Int. Cl. H01L 29/792; H01L 21/28

(52) U.S. Cl. 257/324; 438/591; 257/E21.423; 257/E21.18

(57) ABSTRACT

A gate of a memory device may include a charge trapping structure having a tunnel oxide layer, a charge storing layer, and a blocking layer on a semiconductor substrate; a conductive pattern on the charge trapping structure, the conductive pattern including metal nitride; an ohmic film on the conductive pattern; and a gate electrode on the ohmic film.

### BACKGROUND OF THE INVENTION

1. Field of the Invention

The present invention relates to a memory device and a method of manufacturing the same. More particularly, the present invention relates to a gate of a memory device exhibiting enhanced uniformity of surface resistance, a memory device employing the gate, and a method of manufacturing the gate and the memory device therewith.

2. Description of the Related Art

In general, nonvolatile memory devices refer to semiconductor devices that can retain data. Conventional nonvolatile memory devices may be classified according to types of memory storage layers employed in a unit cell thereof, i.e., floating-gate type memory devices and charge-trapping type memory devices.

The conventional floating-gate type memory device may include a tunnel oxide layer, a floating gate for storing charges, a dielectric layer, and a control gate formed sequentially on a semiconductor substrate in a unit cell. Programming of the floating-gate type memory device may be performed by storing charges in the floating gate, while providing a relatively thick tunnel oxide layer between the floating gate and the semiconductor substrate to minimize charge loss from the floating gate. However, a relatively thick tunnel oxide layer may require high operating voltage, thereby necessitating complex circuitry which may limit an integration degree of the overall floating-gate type memory device.

The conventional charge-trapping type memory device, e.g., a metal-oxide-nitride-oxide-silicon (MONOS) device, may include a multi-layered trap structure having a tunnel oxide layer, a charge storing layer and a blocking layer, a conductive layer, and a gate electrode formed sequentially on a semiconductor substrate in a unit cell. Programming of the charge-trapping type memory device may be performed by storing charges in the multi-layered trap structure, while providing a relatively thin tunnel oxide layer to facilitate charge movement within the trap structure, i.e., provide charge access to inner layers of the trap structure.

The conductive layer of the conventional charge trapping type memory device may be formed of metal nitride, e.g., tantalum nitride, while the gate electrode of the conventional charge-trapping type memory device may be formed of metal or metal nitride as well, e.g., tungsten or tungsten nitride. Such a gate structure may increase a surface resistance of the gate electrode. In particular, the size of the tungsten grains employed in the gate electrode that is in contact with the tantalum nitride of the conductive layer may increase due to the crystalline characteristics of the tantalum nitride layer, thereby modifying the surface resistance of the overall tungsten layer or the tungsten nitride layer with respect to the tungsten grain size. Such a gate structure may provide unstable surface resistance thereof and, thereby, reduce the overall reliability of the memory device.

Accordingly, even though the structure of the tunnel oxide layer of the conventional charge-trapping type memory device may provide improved circuit structure and high-integration capabilities due to a low thickness thereof, there exists a need for an improved structure of a charge-trapping type memory device in order to provide a gate electrode exhibiting enhanced surface resistance uniformity.

### SUMMARY OF THE INVENTION

The present invention is therefore directed to a gate of a memory device, a memory device employing the gate, and a method of manufacturing the same, which substantially overcome one or more of the problems due to the limitations and disadvantages of the related art.

It is therefore a feature of an embodiment of the present invention to provide a gate of a charge-trapping type memory device having enhanced uniformity of surface resistance.

It is another feature of an embodiment of the present invention to provide a memory device employing a gate capable of providing enhanced uniformity of surface resistance.

It is yet another feature of an embodiment of the present invention to provide a method of manufacturing a memory device having a gate capable of providing enhanced uniformity of surface resistance and improved overall reliability.

At least one of the above and other features of the present invention may be realized by providing a gate, including a charge trapping structure having a tunnel oxide layer, a charge storing layer, and a blocking layer on a semiconductor substrate; a conductive pattern on the charge trapping structure, the conductive pattern including metal nitride; an ohmic film on the conductive pattern; and a gate electrode on the ohmic film.

The blocking layer may include aluminum oxide, zirconium oxide, zirconium silicate, hafnium oxide, hafnium silicate or a combination thereof. The conductive pattern may include tantalum nitride or tantalum carbon nitride. The ohmic film may include a metal silicide. The gate electrode may include a multi-layered structure having a metal nitride layer and a metal layer.

In another aspect of the present invention, there is provided a method of forming a gate, including forming a preliminary charge trapping structure on a semiconductor substrate by sequentially disposing a tunnel oxide coating, a charge storing coating and a blocking coating on the semiconductor substrate; disposing a metal nitride layer on the preliminary charge trapping structure to form a conductive layer; disposing a metal silicide layer on the conductive layer to form an ohmic layer; disposing a metal layer on the ohmic layer to form a gate electrode layer; and patterning the preliminary charge trapping structure, the conductive layer, the ohmic layer and the gate electrode layer to form the gate.

Disposing a metal nitride layer on the preliminary charge trapping structure may include disposing tantalum nitride or tantalum carbon nitride. Disposing the metal silicide layer on the conductive layer may include sputtering tungsten silicide. Disposing a metal layer on the ohmic layer may include disposing tungsten and tungsten nitride or tungsten and titanium nitride.

In yet another aspect of the present invention, there is provided a memory device, including a semiconductor substrate having a first area and a second area; a first gate positioned on the first area, the first gate including a charge trapping structure, a conductive pattern having a metal nitride, a first ohmic film having a metal silicide, and a first gate electrode; a second gate positioned on the second area, the second gate electrode including a gate oxide layer, a polysilicon layer, a second ohmic film and a second gate electrode; and source/drain regions at an upper surface of the semiconductor substrate. The source/drain regions may be adjacent to the first and second gates.

The conductive pattern may include tantalum nitride or tantalum carbon nitride. The ohmic film may include a metal silicide. Additionally, the memory device may further include an isolation layer on the upper surface of the semiconductor substrate.

In still another aspect of the present invention, there is provided a method of manufacturing a memory device, including forming first and second areas in a semiconductor substrate; applying a gate oxide coating and a polysilicon coating on the second area of the semiconductor substrate; applying a preliminary charge trapping structure on the polysilicon coating and the first area of the semiconductor substrate; applying a metal nitride layer on the preliminary charge trapping structure to form a conductive layer; removing the conductive layer and the preliminary charge trapping structure from the second area of the semiconductor substrate; forming an ohmic layer on the conductive layer in the first area and on the polysilicon coating in the second area; disposing a metal layer on the ohmic layer to form a gate electrode layer; patterning the gate electrode layer, the ohmic layer, the conductive layer, and the preliminary charge trapping structure in the first area to form a first gate having a gate electrode, a first ohmic film, a conductive pattern, and a charge trapping structure; and patterning the gate electrode layer, the ohmic layer, the polysilicon coating, and the gate oxide coating in the second area to form a second gate having a gate electrode, a second ohmic film, a polysilicon layer, and a gate oxide layer.

The method may further include disposing a middle temperature oxide (MTO) on the polysilicon coating to form a-sacrificial layer. Additionally, the method may include disposing silicon oxide on the conductive layer to form a mask oxide layer pattern. The method may also include simultaneously removing the mask oxide layer pattern and the sacrificial layer.

Disposing a metal nitride layer on the preliminary charge trapping structure may include disposing tantalum nitride or tantalum carbon nitride. Additionally, disposing the metal silicide layer on the conductive layer may include sputtering tungsten silicide.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of a gate according to an exemplary embodiment of the present invention;

FIGS. 2-5 illustrate cross-sectional views of sequential stages during formation of the gate illustrated in FIG. 1;

FIG. 6 illustrates a cross-sectional view of a memory device according to an exemplary embodiment of the present invention;

FIGS. 7 to 12 illustrate cross-sectional views of sequential stages of a method of manufacturing the memory device illustrated in FIG. 6; and

FIG. 13 illustrates a graph comparing surface resistance of a conventional gate and gates formed according to the present invention.

### DETAILED DESCRIPTION OF THE INVENTION

Korean Patent Application No. 2006-92177 filed on Sep. 22, 2006, in the Korean Intellectual Property Office, and entitled: “Gate and Method of Forming the Same, and Memory Device and Method of Manufacturing the Same” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will further be understood that when an element is referred to as being “on” another element, layer or substrate, it can be directly on the other element, layer or substrate, or intervening elements or layers may also be present. Further, it will be understood that when an element or layer is referred to as being “under” another element or layer, it can be directly under, or one or more intervening elements or layers may also be present. In addition, it will also be understood that when an element or layer is referred to as being “between” two elements or layers, it can be the only element or layers between respective two elements or layers, or one or more intervening elements or layers may also be present. Likewise, it will be understood that when an element or layer is referred to as being “connected to” or “coupled to” another element or layer, it can be directly connected to or coupled to the other element or layer, or intervening elements or layers may be present. In contrast, when an element is referred to as being “directly on,” “directly connected to,” or “directly coupled to” another element or layer, there may be no intervening elements or layers present. Like reference numerals refer to like elements or layers throughout.

As used herein, the term “and/or” may include any and all combinations of one or more of the associated listed items. As further used herein, the singular forms “a,” “an” and “the” are intended to include the plural forms as well, unless the context clearly indicates otherwise.

Unless otherwise defined, all terminology used herein is given its ordinary meaning in the art, and therefore, should be interpreted within the context of the specification and the relevant art as understood by one of ordinary skill.

Spatially relative terms, such as “beneath,” “below,” “lower,” “above,” “upper” and the like, may be used herein to describe a relationship of one element or feature to another element(s) or feature(s) as illustrated in the figures. Accordingly, it will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below.

Accordingly, the exemplary embodiments of the present invention should not be construed as limited to the particular shapes of regions illustrated herein but are to include deviations in shapes that result, for example, from manufacturing. For example, a source/drain region illustrated as a rectangle may have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the present invention.

An exemplary embodiment of a gate of a memory device according to the present invention will now be more fully described with respect to FIG. 1.

It should be noted, however, that a gate according to an embodiment of the present invention may be employed in any nonvolatile memory device, e.g., a tantalum-nitride-oxide-silicon (TaNOS) type nonvolatile memory device, a volatile memory device, and so forth, as may be determined by one of ordinary skill in the art.

As illustrated in FIG. 1, a gate 60 may include a charge trapping structure 20a, a conductive pattern 30a, an ohmic film 40a, and a gate electrode 50a that may be sequentially formed on a substrate 10, e.g., a substrate made of single crystalline silicon.

The charge trapping structure 20a may be applied on the substrate 10 and include a multi-layered pattern. In other words, the charge trapping structure 20a may include a tunnel oxide layer 12a, a charge storing layer 14a and a blocking layer 16a applied sequentially on the substrate 10.

The tunnel oxide layer 12a of the charge trapping structure 20a may be applied on the substrate 10 and may provide an energy barrier in electron tunneling. The tunnel oxide layer 12a may include silicon oxide (SiO₂) or silicon oxynitride (SiON) and have a thickness of about 20 angstroms to about 50 angstroms.

The charge storing layer 14a of the charge trapping structure 20a may be formed on the tunnel oxide layer 12a and include a plurality of trap sites (not shown) to store or emit charges therefrom. The plurality of trap sites may be positioned deeply in the charge storing layer 14a, such that charges trapped therein would not be able to leak out. Such trapping of charges may provide enhanced data retention capabilities. Additionally, the charge storing layer 14a may operate as a barrier layer to minimize diffusion of metal from the blocking layer 16a into the tunnel oxide layer 12a.

The charge storing layer 14a may be formed to have a thickness of about 20 angstroms to about 50 angstroms. Preferably, the charge storing layer 14a may have a thickness of about 30 angstroms. A thickness of less than about 20 angstroms may not be sufficient to store charges or minimize metal diffusion. On the other hand, a thickness of more than about 50 angstroms may generate excessive internal stress, thereby impairing an operation of the charge storing layer 14a.

The blocking layer 16a of the charge trapping structure 20a may be formed of a metal oxide material, e.g., aluminum oxide, zirconium oxide, zirconium silicate, hafnium oxide, hafnium silicate, like metal oxide materials, and combinations thereof, and may be applied on the charge storing layer 14a, such that the charge storing layer 14a may be positioned between the tunnel oxide layer 12a and the blocking layer 16a. The metal oxide material in the blocking layer 16a may have a dielectric constant higher than a dielectric constant of materials employed for forming the tunnel oxide layer 12a, e.g., silicon oxide, thereby providing improved voltage passage between the gate electrode 50a and the tunnel oxide layer 12a.

Nonetheless, the blocking layer 16a may block voltage passage from the gate electrode 50a and the conductive pattern 30a toward the charge storing layer 14a. Additionally, the blocking layer 16a may minimize movement of charges between the charge storing layer 14a and the gate electrode 50a when the gate 60 is not active, i.e., when a programming or an erasing operation is not performed.

The conductive pattern 30a of the gate 60 may include a metal or a metal nitride material having a work function above about 4.0 eV, e.g., titanium nitride, tungsten nitride, tantalum nitride, tantalum carbon nitride, and so forth. Accordingly, if the blocking layer 16a includes a metal oxide layer, the conductive pattern 30a may include a layer of tantalum nitride having a work function above about 4.5 eV. In this respect, it should be noted that the conductive pattern 30a may not include polysilicon, thereby reducing a potential Fermi-pinning phenomenon, i.e., a state where Fermi level of the polysilicon may be fixed to a given value.

The ohmic film 40a of the gate 60 may be formed on the conductive pattern 30a and may include a metal silicide to provide a uniform surface resistance of the gate electrode 50a and decrease overall resistance of the gate 60 structure, as will be explained in more detail below.

The gate electrode 50a of the gate 60 may be formed on the ohmic film 40a and may have a multi-layered structure having a metal layer, e.g., a tungsten layer, and a metal nitride layer, e.g., a tungsten nitride layer, a titanium nitride layer, and so forth, to provide a low resistance thereto.

Without intending to be bound by theory, it is believed that formation of the ohmic film 40a between the conductive pattern 30a and the gate electrode 50a may provide a barrier between the metal-nitride/metal layers thereof, thereby minimizing the dependency of the metal grain size, e.g., tungsten, of the electrode gate 50a on the crystalline structure of the metal-nitride, e.g., tantalum nitride, employed in the conductive pattern 30a. Accordingly, the minimized contact between the conductive pattern 30a and the gate electrode 50a may provide improved control of the grain size of the tungsten employed in the gate electrode 50a, thereby facilitating provision of a predetermined and uniform surface resistance of the gate electrode 50a.

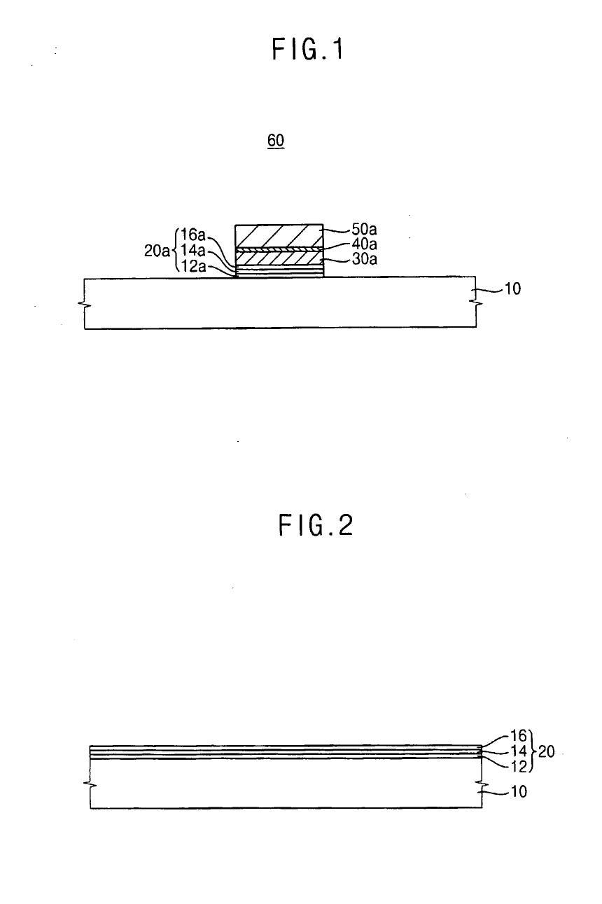

Formation of the gate 60 will be described in more detail with respect to FIGS. 2-5.

As illustrated in FIG. 2, a preliminary charge trapping structure 20 may be formed on a substrate 10 by sequentially depositing a tunnel oxide coating 12, a charge storing coating 14, and a blocking coating 16 on the substrate 10. The tunnel oxide coating 12 may be formed of silicon oxide or silicon oxynitride by, for example, a thermal oxidation process to a thickness of about 10 angstroms to about 50 angstroms. The charge storing coating 14 may be formed by depositing a silicon nitride layer with a plurality of trap sites on the tunnel oxide coating 12 to a thickness of about 20 angstroms to about 50 angstroms, and preferably to a thickness of about 30 angstroms. The blocking coating 16 may be formed by depositing a metal oxide layer with a dielectric constant higher than that of oxide or silicon oxide, e.g., aluminum oxide, zirconium oxide, zirconium silicate, hafnium oxide, hafnium silicate, and so forth, by chemical vapor deposition (CVD) or atomic layer deposition (ALD) on the charge storing coating 14 to a thickness of about 20 angstroms to about 50 angstroms.

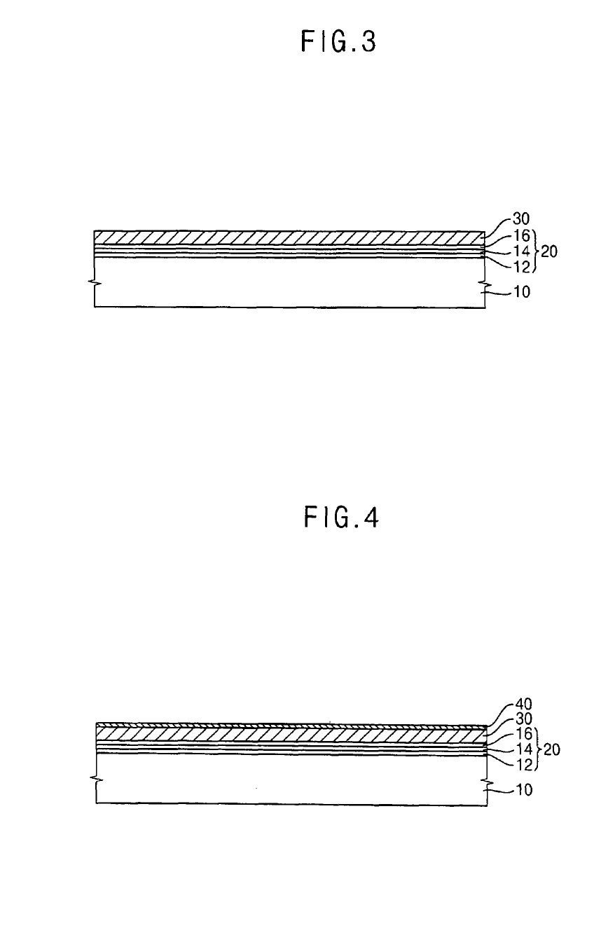

A conductive layer 30 may be formed on the preliminary charge trapping structure 20, as illustrated in FIG. 3. The conductive layer 30 may be formed of a metal or a metal nitride having a work function above about 4.0 eV, e.g., titanium nitride, tantalum nitride, tantalum carbon nitride, and so forth, to a thickness of about 150 angstroms to about 300 angstroms, and preferably to a thickness of about 200 angstroms. For example, the conductive layer 30 may be formed of tantalum nitride by a low-pressure chemical vapor deposition (LPCVD) process or an ultra-high vacuum chemical vapor deposition (UHVCVD) process followed by an additional heat treatment process.

As illustrated in FIG. 4, an ohmic layer 40 may be formed by depositing a metal silicide layer to a thickness of about 30 angstroms to about 100 angstroms, and preferably to a thickness of about 50 angstroms, on the conductive layer 30 by sputtering. The ohmic layer 40 may include amorphous silicon.

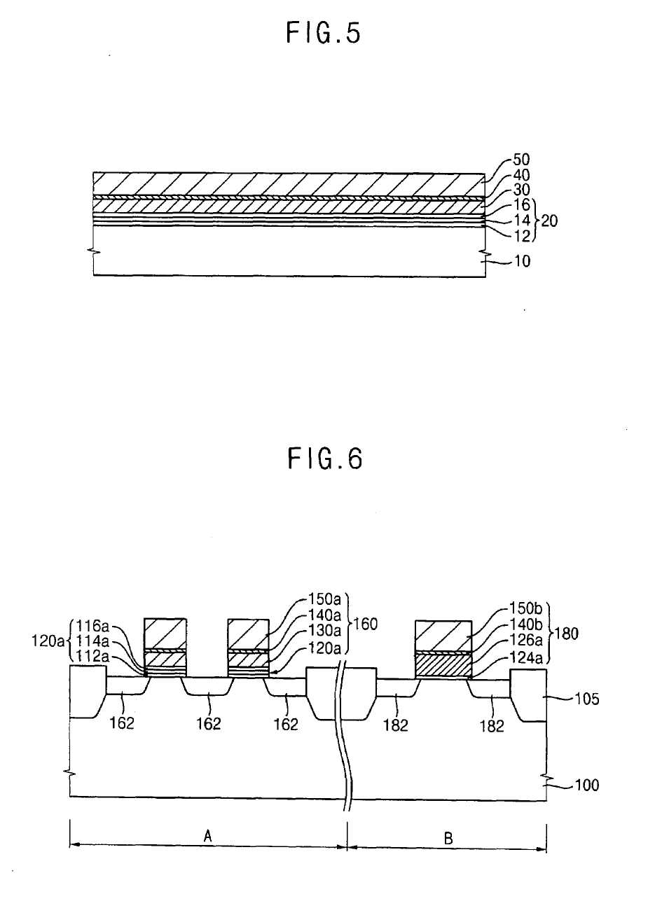

As illustrated in FIG. 5, a gate electrode layer 50 may be formed by depositing a metal layer on the ohmic layer 40, such that a resistance of the gate 60 may be minimized. In particular, the gate electrode layer 50 may be formed to have a multi-layered structure including a metal layer, e.g., a tungsten layer, and a metal nitride layer, e.g., a tungsten nitride layer, a titanium nitride layer, and so forth. The gate electrode layer 50 may be formed on the ohmic layer 40, such that a size of the tungsten grains included in the gate electrode layer 50 may be controlled to be sufficiently large to provide a uniform surface resistance thereto as previously described with respect to the gate electrode 50a in FIG. 1. Accordingly, and without intending to be bound by theory, it is believed that the resistance of the gate electrode 50a upon application of voltage from the gate electrode 50a to the charge trapping structure 20a via the conductive pattern 30a may be relatively low.

An etching mask (not shown) may be applied to the gate electrode layer 50, and the gate electrode layer 50, the ohmic layer 40, the conductive layer 30 and the preliminary charge trapping structure 20 may be etched by an etching process to form the gate 60 having the charge trapping structure 20a, the conductive pattern 30a, the ohmic film 40a and the gate electrode 50a, as illustrated in FIG. 1. Alternatively, only the gate electrode layer 50, the ohmic layer 40, and the conductive layer 30 may be etched, such that the gate 60 may include the conductive pattern 30a, the ohmic film 40a and the gate electrode 50a sequentially stacked on the preliminary charge trapping structure 20.

In another aspect of the present invention, an exemplary embodiment of a memory device employing a gate as previously described with respect to FIGS. 1-5 will be more fully described with respect to FIG. 6. A memory device according to an exemplary embodiment of the present invention may be a nonvolatile memory device, e.g., a TaNOS NAND flash memory device. However, volatile memory devices are not excluded from the scope of the present invention.

As illustrated in FIG. 6, a memory device according to an embodiment of the present invention may include a semiconductor substrate 100, an isolation layer 105, at least one first gate 160, and at least one second gate 180. In this respect, it should be noted that descriptive terms such as “first” and “second” may refer to elements of an embodiment of the present invention for the purpose of distinguishing one element from another only.

The semiconductor substrate 100 may be any suitable semiconductor substrate as determined by one of ordinary skill in the art, such as a silicon substrate, a silicon-on-insulator (SOI) substrate, a germanium substrate, a germanium-on-insulator (GOI) substrate, a silicon-germanium substrate, an epitaxial thin film substrate formed by a selective epitaxial growth (SEG) technique, and so forth. Additionally, the semiconductor substrate 100 may be divided into a first area A and a second area B, such that the first area A may function as a cell area having a plurality of unit cells and the second area B may function as a peripheral area having a plurality of peripheral circuits.

The isolation layer 105 of the memory device according to an embodiment of the present invention may be formed on an upper surface of the semiconductor substrate 100 of a field oxide layer, a trench isolation layer, or a like material to define active and field regions therein. Accordingly, the isolation layer 105 may define a high voltage region and a low voltage region in the second area B.

The first gate 160 of the memory device according to an embodiment of the present invention may be formed on the first area A of the semiconductor substrate 100 and may include a charge trapping structure 120a, a conductive pattern 130a, a first ohmic film 140a and a first gate electrode 150a. The charge trapping structure 120a of the first gate 160 may have a multi-layered pattern having a tunnel oxide layer 112a, a charge storing layer 114a, and a blocking layer 116a. The structure of the first gate 160 may be similar to the structure of the gate 60 previously described with respect to FIGS. 1-5. Accordingly, detailed description of the structure of the first gate 160 will not be repeated herein.

The second gate 180 of the memory device according to an embodiment of the present invention may be formed on the second area B of the semiconductor substrate 100 and may include a gate oxide layer 124a, a polysilicon layer 126a, a second ohmic film 140b and a second gate electrode 150b. The second gate 180 may function as a gate of a metal-oxide-semiconductor (MOS) transistor.

The gate oxide layer 124a of the second gate 180 may be formed of silicon oxide, silicon oxynitride, metal oxide, or any other like material on the second area B of the semiconductor substrate 100. Further, the gate oxide layer 124a may be formed to have a thickness below about 50 angstroms, when the gate oxide layer 124a is formed in the low voltage region. On the other hand, the gate oxide layer 124a may be formed to have a thickness above about 90 angstroms, when the gate oxide layer 124a is formed in the high voltage region.

The polysilicon layer 126a of the second gate 180 may include impurities from Group III of the periodic table and may be formed on the gate oxide layer 124a, such that the polysilicon layer 126a may function as an electrode of the second gate 180.

The second ohmic film 140b of the second gate 180 may be formed of a metal silicide and deposited on the polysilicon layer 126a. The second ohmic film 140b may enhance uniformity of a surface resistance of the second gate electrode 150b and decrease a resistance at an interface between the polysilicon film 126a and the second gate electrode 150b.

The second gate electrode 150b of the second gate 180 may be formed of a single-layered pattern or a multi-layered pattern, e.g., a tungsten film and a tungsten nitride film. The second gate electrode 150b may apply voltage to the gate oxide layer 124a through the polysilicon layer 126a.

The memory device according to an embodiment of the present invention may also include first and second source/drain regions 162 and 182, respectively. The source/drain regions 162 and 182 may include impurities from Group V of the periodic table, e.g., phosphorus, arsenic, like materials, or combination thereof, and be formed at an upper surface of the semiconductor substrate 100. In particular, the first source/drain region 162 may be formed in the first region A, such that each first gate 160 may be positioned between two first source/drain regions 162. Similarly, the second source/drain region 182 may be formed in the second region B, such that each second gate 180 may be positioned between two second source/drain regions 182.

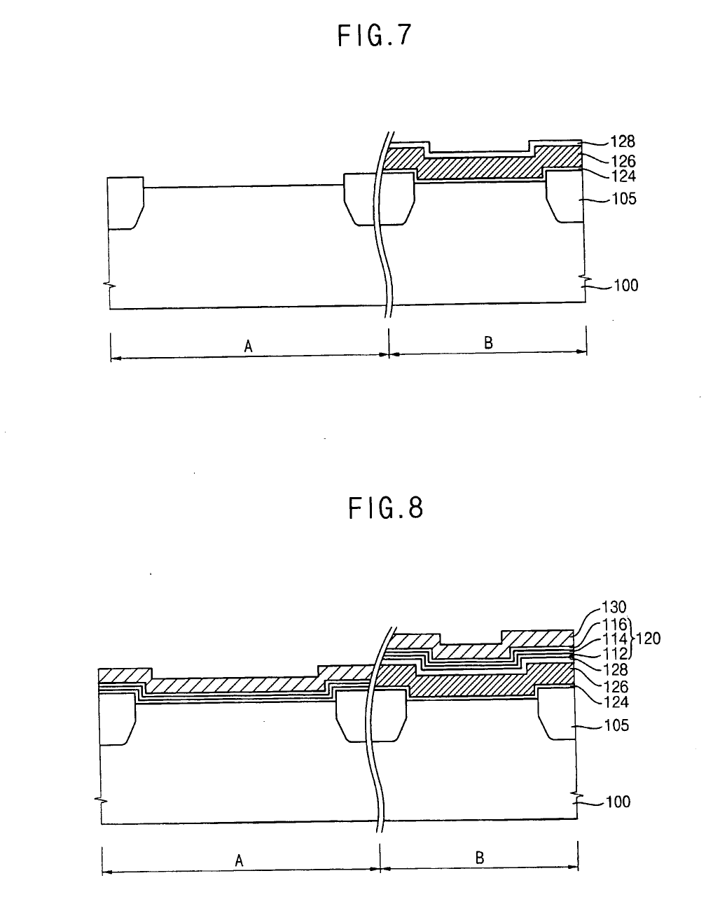

Manufacturing of the memory device according to an embodiment of the present invention will be described in more detail with respect to FIGS. 7-12.

As illustrated in FIG. 7, a semiconductor substrate 100 may be divided into a first area A and a second area B, and an isolation layer 105 may be formed on an upper surface of each of the first and second areas A and B. Each of the first and second areas A and B may be treated independently. First, a gate oxide coating 124, a polysilicon coating 126, and a sacrificial layer 128 may be applied sequentially on the upper surface of the second area B of the semiconductor substrate 100. In particular, a preliminary oxide layer (not shown), e.g., silicon oxide, may be applied on the semiconductor substrate 100 by thermal oxidation or CVD. A preliminary polysilicon layer (not shown) with Group III impurities may be applied on the preliminary oxide layer, and a middle temperature oxide (MTO) may be applied on the preliminary polysilicon layer to form a preliminary sacrificial layer (not shown).

A first etching mask (not shown), e.g., a photoresist pattern or a silicon nitride layer, may be applied on the preliminary sacrificial layer to cover the second area B. Subsequently, the preliminary sacrificial layer, the preliminary polysilicon layer and the preliminary oxide layer may be partially removed using the first etching mask to form the gate oxide coating 124, the polysilicon coating 126 and the sacrificial layer 128. Once the gate oxide coating 124, the polysilicon coating 126 and the sacrificial layer 128 are formed, the first etching mask may be removed sufficiently.

Illustrated in FIG. 8, a preliminary charge trapping structure 120 having a tunnel oxide coating 112, a charge storing coating 114 and a blocking coating 116 may be formed on each of the first and second areas A and B of the semiconductor substrate 100 to have a substantially uniform thickness. In particular, the preliminary charge trapping structure 120 may be applied on the sacrificial layer 128 of the second area B of the semiconductor substrate 100. Similarly, the preliminary charge trapping structure 120 may be deposited on the upper surface of the first area A of the semiconductor substrate 100. More specifically, the tunnel oxide coating 112 may be formed by, for example, thermal oxidation or CVD on the sacrificial layer 128. The charge storing coating 114 may be formed by depositing a silicon nitride layer with a plurality of trap sites on the tunnel oxide coating 112 to a thickness of about 20 angstroms to about 50 angstroms, and preferably to a thickness of about 30 angstroms. The blocking coating 116 may be formed by depositing a metal oxide layer with a dielectric constant higher than that of oxide or silicon oxide, e.g., aluminum oxide, zirconium oxide, zirconium silicate, hafnium oxide, hafnium silicate, and so forth, by CVD or ALD on the charge storing coating 114 to a thickness of about 20 angstroms to about 50 angstroms.

A conductive layer 130 may be formed on the preliminary charge trapping structure 120 on both first and second areas A and B of the semiconductor substrate 100. The conductive layer 130 may be formed of a metal or a metal nitride having a work function above about 4.0 eV, e.g., titanium nitride, tantalum nitride, tantalum carbon nitride, and so forth, to a uniform thickness of about 150 angstroms to about 300 angstroms by LPCVD or UHVCVD.

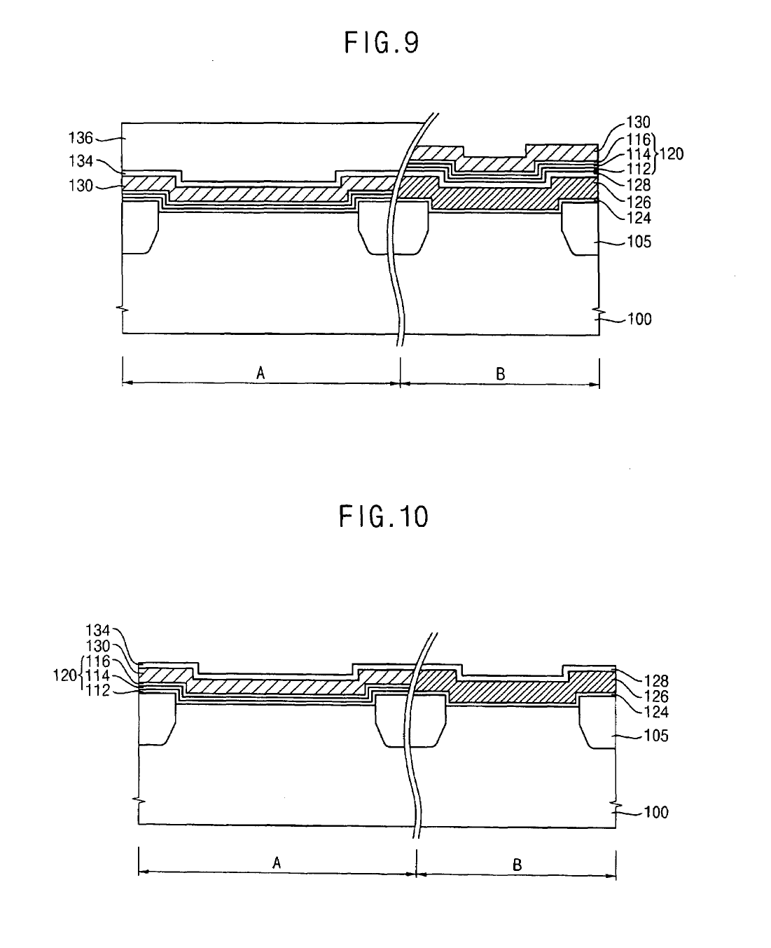

Illustrated in FIG. 9, a mask oxide layer pattern 134 and a second etching mask 136 may be deposited on a portion of the conductive layer 130 in the first area A. In particular, a mask oxide layer (not shown) may be formed on the conductive layer 130 by a plasma-enhanced chemical vapor deposition (PECVD) to a uniform thickness of about 1500 angstroms. The second etching mask 136 may be formed on the mask oxide layer by using a photoresist pattern. The mask oxide layer may be partially removed by an etching process using the second etching mask 136 to form the mask oxide layer pattern 134 in the first area A. Alternatively, the mask oxide layer pattern 134 may not be formed on the conductive layer 130.

A portion of the conductive layer 130 and a portion of the preliminary charge trapping structure 120 deposited on the second area B of the semiconductor substrate 100, i.e., portions of the conductive layer 130 and the preliminary charge trapping structure 120 that are not covered by the mask oxide layer pattern 134, may be removed by etching, e.g., dry etching process using plasma, to expose the sacrificial layer 128 in the second area B, as illustrated in FIG. 10. The conductive layer 130 and the preliminary charge trapping structure 120 may remain in the first area A, as further illustrated in FIG. 10, after removing the second etching mask 136 by an ashing process using oxygen plasma and/or a stripping process using an etching solution.

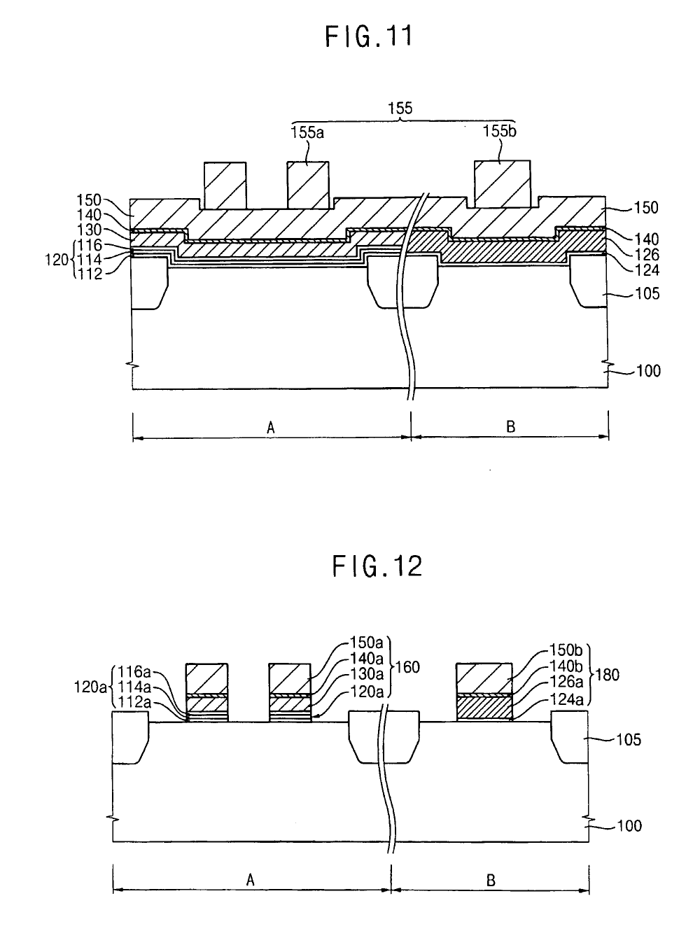

As illustrated in FIG. 11, the mask oxide layer pattern 134 may be removed from the first area A and the sacrificial layer 128 may be removed from the second area B. The removal of the mask oxide layer pattern 134 and the sacrificial layer 128 may be performed simultaneously by a wet etching process using oxide etching solution.

Once the mask oxide layer pattern 134 and the sacrificial layer 128 are removed, the ohmic layer 140 may be formed on the conductive layer 130 of the first area A and the polysilicon layer of the second area B by depositing a metal silicide layer, e.g., a tungsten silicide layer, thereon to a uniform thickness of about 30 angstroms to about 100 angstroms by a sputtering process. Additionally, a barrier layer (not shown) may be further formed on the ohmic layer 140.

The gate electrode layer 150 may be formed on the ohmic layer 140. In particular, the gate electrode layer 150 may be formed by depositing a single-layer of metal, e.g., a tungsten layer, a titanium layer, and so forth, or a multi-layer of metal and metal nitride, e.g., a tungsten layer and a tungsten nitride layer.

Without intending to be bound by theory, it is believed that formation of the ohmic layer 140 between the conductive layer 130 and the gate electrode layer 150 may facilitate control of the grain size of tungsten included in the gate electrode layer 150. In particular, the ohmic layer 140 may minimize effects of the conductive layer 130 on the gate electrode layer 150, thereby facilitating formation of the tungsten grains included in the gate electrode layer 150 to a sufficiently large and uniform size. Sufficiently large and uniform size of tungsten grains in the gate electrode layer 150 may increase uniformity of the surface resistance thereof. Accordingly, a memory device employing a gate having an ohmic layer between a gate electrode and a conductive layer thereof may have a uniform programming/erasing speed, thereby facilitating use thereof in additional fields.

A hard mask 155 may be formed of silicon nitride on the gate electrode layer 150 to define sizes of the first and the second gates 160 and 180. In particular, the hard mask 155 may include a first hard mask 155a to define a size of the first gate 160 and a second hard mask 155b to define a size of the second gate 180.

As illustrated in FIG. 12, the first area A of the semiconductor substrate 100 may be etched according to the first hard mask 155a to form the first gate 160 having the charge trapping structure 120a, the conductive pattern 130a, the first ohmic film 140a, and the first gate electrode 150a Similarly, the second area B of the semiconductor substrate 100 may be etched according to the second hard mask 155b to form the second gate 180 having the gate oxide layer 124a, the polysilicon layer 126a, the second ohmic film 140b, and the second gate electrode 150b.

The first and the second etching processes, i.e., etching of the first and second areas A and B, may be performed simultaneously or sequentially.

Alternatively, the first etching process may be performed to partially remove the gate electrode layer 150, the ohmic layer 140 and the conductive layer 130, such that the preliminary charge trapping structure 120a, the conductive pattern 130a, the first ohmic layer pattern 140a and the first gate electrode 150a may be sequentially formed on the first area A of the semiconductor substrate 100.

Impurities may be implanted onto portions of the upper surface of the semiconductor substrate 100 using the first and the second gates 160 and 180 as masks. Accordingly, the source/drain regions 162 and 182 may be formed at the upper portions of the semiconductor substrate 100 adjacent to the first and the second gates 160 and 180 to complete the memory device, e.g., a TaNOS type memory device, according to an embodiment of the present invention. In this respect, it should be noted that in the exemplary embodiment of the present invention the memory device may have a planar type gate. However, other types of gate, e.g., a vertical-type gate, a fin-type gate, and so forth, are not excluded from the scope of the present invention.

### EXAMPLES

In the following experimental examples a conventional gate of a memory device and two gates formed according to the present invention, i.e., gates having an ohmic layer, were prepared and compared with respect to the surface resistance thereof.

The gates were formed as follows. The conventional gate was prepared by sequentially applying a tungsten layer, a tungsten nitride layer, and a polysilicon layer to a semiconductor substrate.

The gates formed according to the present invention were prepared by applying an ohmic layer between the metal nitride layer and the polysilicon layer. In other words, the first gate according to the present invention was formed to have a tungsten layer, a titanium nitride layer, an ohmic layer of tungsten silicide, and a polysilicon layer. The second gate was formed to have a tungsten layer, a tungsten nitride layer, an ohmic layer of tungsten silicide, and a polysilicon layer.

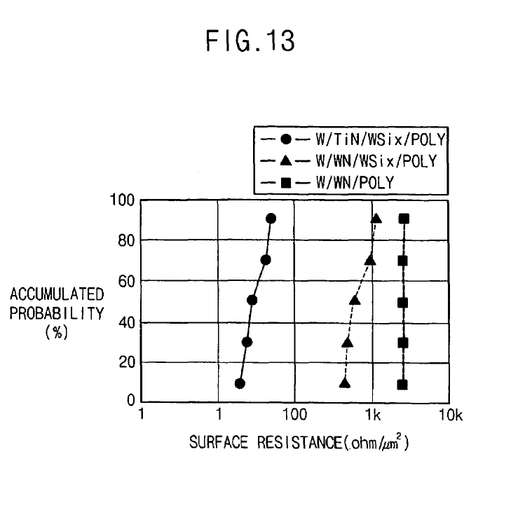

Results of the comparison are illustrated in a graphic form in FIG. 13.

In particular, the first and second gates are represented by -- and -▴- symbols, respectively. The conventional gate is represented by a -▪- symbol.

As can be seem in FIG. 13, the conventional gate had a high surface resistance of about 5000 Ω/μm² at an accumulated probability of about 50%. The first gate, on the other hand, had a surface resistance of about 50 Ω/μm² at the accumulated probability of about 50%, and the second gate had a surface resistance of about 850 Ω/μm² at the accumulated probability of about 50%. In other words, the first and second gates, i.e., gates having an ohmic layer of tungsten silicide, exhibited surface resistance that is at least 6 times lower as compared to the surface resistance of the conventional gate.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A gate, comprising:
a charge trapping structure having a tunnel oxide layer, a charge storing layer, and a blocking layer on a semiconductor substrate;
a conductive pattern on the charge trapping structure, the conductive pattern including metal nitride;
an ohmic film on the conductive pattern; and
a gate electrode on the ohmic film.

2. The gate as claimed in claim 1, wherein the blocking layer includes aluminum oxide, zirconium oxide, zirconium silicate, hafnium oxide, hafnium silicate or a combination thereof.

3. The gate as claimed in claim 1, wherein the conductive pattern includes tantalum nitride or tantalum carbon nitride.

4. The gate as claimed in claim 1, wherein the ohmic film includes a metal silicide.

5. The gate as claimed in claim 1, wherein the gate electrode includes a multi-layered structure having a metal nitride layer and a metal layer.

6. A method of forming a gate, comprising:
forming a preliminary charge trapping structure on a semiconductor substrate by sequentially disposing a tunnel oxide coating, a charge storing coating and a blocking coating on the semiconductor substrate;
disposing a metal nitride layer on the preliminary charge trapping structure to form a conductive layer;
disposing a metal silicide layer on the conductive layer to form an ohmic layer;
disposing a metal layer on the ohmic layer to form a gate electrode layer; and
patterning the preliminary charge trapping structure, the conductive layer, the ohmic layer and the gate electrode layer to form the gate.

7. The method as claimed in claim 6, wherein disposing a metal nitride layer on the preliminary charge trapping structure includes disposing tantalum nitride or tantalum carbon nitride.

8. The method as claimed in claim 6, wherein disposing the metal silicide layer on the conductive layer includes sputtering tungsten silicide.

9. The method as claimed in claim 6, wherein disposing a metal layer on the ohmic layer includes disposing tungsten and tungsten nitride or tungsten and titanium nitride.

10. A memory device, comprising:
a semiconductor substrate having a first area and a second area;
a first gate positioned on the first area, the first gate including a charge trapping structure, a conductive pattern having a metal nitride, a first ohmic film having a metal silicide, and a first gate electrode;
a second gate positioned on the second area, the second gate electrode including a gate oxide layer, a polysilicon layer, a second ohmic film and a second gate electrode; and
source/drain regions at an upper surface of the semiconductor substrate.

11. The memory device as claimed in claim 10, wherein the conductive pattern includes tantalum nitride or tantalum carbon nitride.

12. The memory device as claimed in claim 10, wherein the first and second ohmic films include a metal silicide.

13. The memory device as claimed in claim 10, further comprising an isolation layer on the upper surface of the semiconductor substrate.

14. The memory device as claimed in claim 10, wherein the source/drain regions are adjacent to the first and second gates.

15. A method of manufacturing a memory device, comprising:
forming first and second areas in a semiconductor substrate;
applying a gate oxide coating and a polysilicon coating on the second area of the semiconductor substrate;
applying a preliminary charge trapping structure on the polysilicon coating and on the first area of the semiconductor substrate;
applying a metal nitride layer on the preliminary charge trapping structure to form a conductive layer;
removing the conductive layer and the preliminary charge trapping structure from the second area of the semiconductor substrate;
forming an ohmic layer on the conductive layer in the first area and on the polysilicon coating in the second area;
disposing a metal layer on the ohmic layer to form a gate electrode layer; and
patterning the gate electrode layer, the ohmic layer, the conductive layer, and the preliminary charge trapping structure on the first area to form a first gate having a gate electrode, a first ohmic film, a conductive pattern, and a charge trapping structure; and
patterning the gate electrode layer, the ohmic layer, the polysilicon coating, and the gate oxide coating in the second area to form a second gate having a gate electrode, a second ohmic film, a polysilicon layer, and a gate oxide layer.

16. The method as claimed in claim 15, further comprising disposing a middle temperature oxide (MTO) on the polysilicon coating to form a sacrificial layer.

17. The method as claimed in claim 16, further comprising disposing silicon oxide on the conductive layer to form a mask oxide layer pattern.

18. The method as claimed in claim 17, further comprising simultaneously removing the mask oxide layer pattern and the sacrificial layer.

19. The method as claimed in claim 13, wherein disposing a metal nitride layer on the preliminary charge trapping structure includes disposing tantalum nitride or tantalum carbon nitride.

20. The method as claimed in claim 13, wherein disposing the metal silicide layer on the conductive layer includes sputtering tungsten silicide.
